(19) United States
(12) Patent Application Publication
(10) Pub. No.: US 2021/0400853 A1
(43) Pub. Date: Dec. 23, 2021

(54) DISPLAY DEVICE

(71) Applicant: SAMSUNG ELECTRONICS CO., LTD., Suwon-si (KR)

(72) Inventor: Woo Sub CHOI, Suwon-si (KR)

(73) Assignee: SAMSUNG ELECTRONICS CO., LTD., Suwon-si (KR)

(21) Appl. No.: 17/292,325

(22) PCT Filed: Oct. 23, 2019
(86) PCT No.: PCT/KR2019/013994

§ 371 Date: May 7, 2021

(30) Foreign Application Priority Data
Nov. 9, 2018 (KR) 10-20148-0137224

(51) Int. Cl. H05K 7/20

(52) U.S. Cl. CPC H05K 7/20972

(57) ABSTRACT

A display apparatus comprises a display panel, a cabinet provided to support the display panel and including a first cooling space and a second cooling space, a first inlet provided to allow air outside the cabinet to flow into the first cooling space, a second inlet provided to allow air outside the cabinet to flow into the second cooling space, a first fan configured to discharge air inside the second cooling space to the first cooling space, and a first outlet provided to allow air to flow from the first cooling space to an outside of the cabinet.

### TECHNICAL FIELD

The present disclosure relates to a display apparatus including a heat dissipation structure.

### BACKGROUND ART

A display apparatus is a type of output device that visually displays data information such as characters and figures, and images. There is a growing need of high luminance, high resolution, large size, high efficiency, and low power for display apparatus. In addition, such display apparatus is often installed outdoors for the purpose of advertisements or the like.

A high-luminance display apparatus or an outdoor display apparatus generates a large amount of heat because of its high luminance. In addition, in the outdoor display apparatus, when a display panel is directly exposed to sunlight, a surface temperature of the panel may increase, resulting in deterioration. When the display apparatus is provided with a backlight unit, the display panel may be deteriorated by heat generated by the backlight unit.

Accordingly, the display apparatus includes a heat dissipation structure for discharging heat generated by a display panel and heat generated inside the display apparatus. The heat dissipation structure for cooling the display apparatus uses natural or forced convection, or a heat exchanger used in a refrigerator or an air conditioner.

However, it is difficult to sufficiently cool a heat-generating component through the natural convection, and, forced convection has poor heat exchange efficiency, and the heat exchanger causes a complex system.

### DISCLOSURE

### Technical Problem

The present disclosure is directed to providing a display apparatus including a heat dissipation structure capable of simultaneously cooling two separate spaces with a single fan.

Further, the present disclosure is directed to providing a display apparatus including a heat dissipation structure capable of performing cooling with air introduced by a fan at high speed and air sucked due to a decrease in an internal air pressure.

Further, the present disclosure is directed to providing a display apparatus capable of minimizing an influence of dust and moisture contained in air flowing from the outside for cooling.

### Technical Solution

One aspect of the present disclosure provides a display apparatus including a display panel, a cabinet provided to support the display panel and including a first cooling space and a second cooling space, a first inlet provided to allow air outside the cabinet to flow into the first cooling space, a second inlet provided to allow air outside the cabinet to flow into the second cooling space, a first fan configured to discharge air inside the second cooling space to the first cooling space, and a first outlet provided to allow air to flow from the first cooling space to an outside of the cabinet.

The display apparatus may further include a heat-generating element disposed in the second cooling space.

The first fan may be configured to discharge air toward the first outlet.

The first fan may include a centrifugal fan.

The display apparatus may further include a filter disposed in the second inlet.

The cabinet may further include a third cooling space, and the display apparatus may further include a second fan configured to discharge air to the third cooling space.

The first cooling space may be disposed on one side of the second cooling space and the third cooling space may be disposed on an opposite side of the second cooling space.

The outlet of the first cooling space and an outlet of the third cooling space may be provided on sides of the cabinet facing to each other, and the first fan and the second fan may be disposed to discharge air to opposite directions to each other.

The cabinet may include an inner wall provided to define the first cooling space and the second cooling space. The inner wall may include a second outlet provided to allow air to flow from the second cooling space to the first cooling space. The first fan may be disposed in the second outlet.

The inner wall may be formed to be convex toward an inside of the first cooling space to allow an area of a cross section, which is perpendicular to an air flow direction, of the first cooling space to be reduced. The second outlet may be disposed adjacent to a region having the smallest cross-sectional area of the first cooling space.

The cabinet may include a surface formed to be convex toward an inside of the first cooling space to allow an area of a cross section, which is perpendicular to an air flow direction, of the first cooling space to be reduced.

The first fan may be disposed on a region having the smallest cross-sectional area of the first cooling space to allow air to flow into the first cooling space.

The first inlet and the first outlet may be provided on sides of the cabinet facing to each other.

The cabinet may further include a first auxiliary inlet provided on other side on which the first inlet or the first outlet is not formed.

The inner wall may include a second auxiliary inlet provided to allow air inside the first cooling space to flow into the second cooling space.

Another aspect of the present disclosure provides a display apparatus including a display panel, a cabinet provided to support the display panel, at least one first cooling space provided inside the cabinet and provided to allow air outside the cabinet to be introduced and provided to allow air to be discharged to an outside of the cabinet, and at least one second cooling space provided inside the cabinet and provided to allow air outside the cabinet to be introduced and provided to allow air to be discharged to the first cooling space.

The display apparatus may further include at least one fan configured to discharge air inside the at least one second cooling space to the at least one first cooling space.

The at least one fan may be configured to discharge air of the second cooling space to an outlet of the at least one first cooling space.

At least one surface among surfaces surrounding the at least one first cooling space may include a surface formed to be convex toward an inside of the first cooling space.

The at least one fan may be disposed on a region having the smallest cross-sectional area, which is perpendicular to an air flow direction of the first cooling space, to allow air to flow into the first cooling space.

### Advantageous Effects

A display apparatus may have high efficiency at low cost by simultaneously cooling two separate spaces with a single fan.

A display apparatus may have high efficiency by including a heat dissipation structure in which outside air is additionally introduced from an inlet due to a decrease in an internal air pressure caused by air introduced at high speed by a fan.

A display apparatus may minimize an influence of dust and moisture contained in air flowing from the outside because the display apparatus includes a structure configured to cool a space, in which electronic components are disposed, separately from other space.

### DESCRIPTION OF DRAWINGS

FIG. 1 is a perspective view of a display apparatus according to one embodiment of the present disclosure.

FIG. 2 is a perspective view of a cabinet of the display apparatus of FIG. 1.

FIG. 3 is a front view of the cabinet of the display apparatus of FIG. 1.

FIG. 4 is a front view of a cabinet of a display apparatus according to another embodiment of the present disclosure.

FIG. 5 is a front view of a cabinet of a display apparatus according to still another embodiment of the present disclosure.

FIG. 6 is a front view of a cabinet of a display apparatus according to still another embodiment of the present disclosure.

### MODES OF THE INVENTION

Embodiments described in the disclosure and configurations illustrated in the drawings are merely examples of the embodiments of the disclosure, and may be modified in various different ways at the time of filing of the present application to replace the embodiments and drawings of the disclosure.

Parts which are not associated with the description are omitted in order to specifically describe the disclosure, and like reference numerals refer to like elements throughout the specification. The size and thickness of each component illustrated in the drawings may be enlarged for clear expressions.

Also, the terms used herein are used to describe the embodiments and are not intended to limit and/or restrict the disclosure. The singular forms “a,” “an” and “the” are intended to include the plural forms as well, unless the context clearly indicates otherwise. In this disclosure, the terms “including”, “having”, and the like are used to specify features, numbers, steps, operations, elements, components, or combinations thereof, but do not preclude the presence or addition of one or more of the features, elements, steps, operations, elements, components, or combinations thereof.

It will be understood that, although the terms first, second, third, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

Hereinafter, exemplary embodiments of the present disclosure will be described in detail with reference to the accompanying drawings.

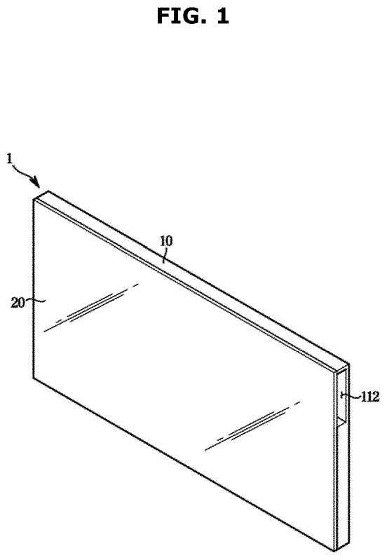

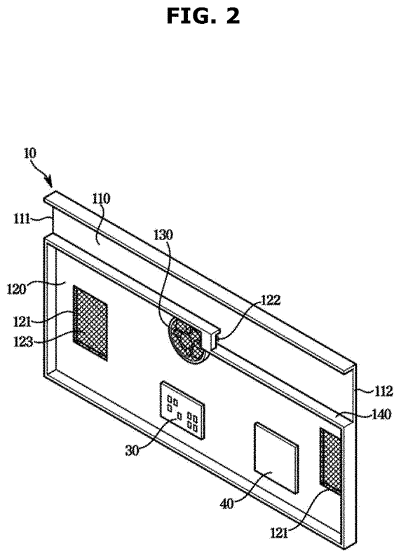

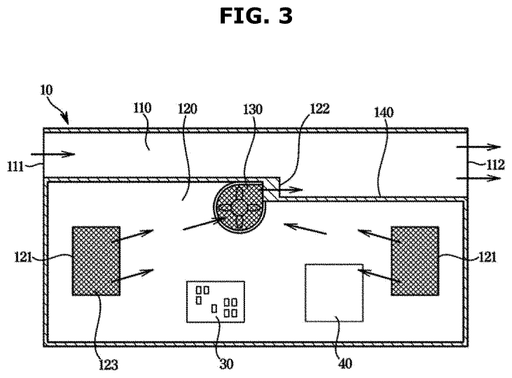

FIG. 1 is a perspective view of a display apparatus according to one embodiment of the present disclosure, FIG. 2 is a perspective view of a cabinet of the display apparatus of FIG. 1, and FIG. 3 is a front view of the cabinet of the display apparatus of FIG. 1.

Referring to FIGS. 1 to 3, a display apparatus 1 is a device configured to display information, materials, data and the like with characters, figures, graphs, images, etc., and a television (TV), a personal computer (PC), a mobile device, or a digital signage may be implemented as a display apparatus. Recently, the high-luminance, the thin and the large size display apparatus have become popular, and thus the more efficient heat dissipation structure for the display apparatus is required.

According to one embodiment of the present disclosure, the display apparatus 1 may include a cabinet 10 and a display panel 20 installed in the cabinet 10. The cabinet 10 may support the display panel 20. The cabinet 10 may be installed on the floor through a stand (not shown), or may be installed on a wall through a hanger (not shown).

The display panel 20 may include a liquid crystal panel (LCD) or an organic light emitting diode (OLED) panel formed by depositing an organic light emitting diode (OLED) on a substrate. In addition, recently, a micro light emitting diode (LED) has been studied as a new panel, and the micro LED panel is formed in such a way that an inorganic light emitting element is mounted on a substrate and the inorganic light emitting element itself is used as a pixel.

The micro LED panel does not need a backlight, thereby minimizing a bezel. Therefore, it is possible that the micro LED panel is compact and thin, and the micro LED panel has excellent luminance, resolution, power consumption, and durability. In addition, the micro LED panel does not require other complicated processes other than a process of picking up inorganic light-emitting elements from a wafer and transferring the inorganic light-emitting elements to a substrate. Therefore, the micro LED panel may be manufactured in various resolutions and sizes according to the customer's order and it is easy to implement a large-size screen because the micro LED panel is assembled as a unit module.

The display panel 20 needs to be cooled as a whole to prevent deterioration. Particularly, when the backlight unit is disposed on a rear surface of the display panel 20, it is required to cool the backlight unit.

Further, the display apparatus 1 may include a power supply device 40 configured to supply power to the display panel 20 and a control board 30 configured to control an operation of the display panel 20. The control board 30 and the power supply device 40 for driving the display apparatus 1 are components that generate a large amount of heat. Therefore, the heat-generating components need a structure configured to dissipate a large amount of heat.

Accordingly, the cabinet 10 provided to support the display panel 20 or the backlight unit (not shown) from the rear side includes a first cooling space 110 and a second cooling space 120. There is no particular limitation in the size and location of the first cooling space 110 and the second cooling space 120. However, components such as the control board 30 and the power supply device 40 for driving the display apparatus 1 are disposed in the second cooling space 120 separated from the first cooling space 110.

The first cooling space 110 is a space for cooling only the display panel 20 or the backlight unit because other components or devices are not disposed in the first cooling space 110. The first cooling space 110 includes a first inlet 111 provided to allow air outside the cabinet 10 to be introduced, and a first outlet 112 provided to allow air to be discharged to an outside of the cabinet 10. The first inlet 111 and the first outlet 112 may be disposed to face each other. The first inlet 111 and the first outlet 112 may be provided on sides of the cabinet 10 facing each other.

Components or devices such as the control board 30 and the power supply device 40 may be vulnerable to dust or moisture contained in outside air introduced for cooling. In addition, components such as the control board 30 and the power supply device 40 are heat-generating components, and thus a structure configured to discharge a large amount of heat is required.

Accordingly, in the second cooling space 120 in which a heat-generating element such as the control board 30 and the power supply device 40 is disposed, a filter 123 configured to filter out dust and moisture may be arranged in a second inlet 121 provided to allow air outside the cabinet 10 to be introduced. Further, the display apparatus 1 may include a fan 130 configured to perform forced convection in the second cooling space 120. The fan 130 may be configured to discharge air inside the second cooling space 120 to the first cooling space 110. The cold outside air of the cabinet 10 flows into the second cooling space 120 through the second inlet 121 due to the rotation of the fan 130. Air entering through the second inlet 121 is discharged to the first cooling space 110 by the fan 130 after cooling the heat-generating elements 30 and 40 and the display panel 20.

The cabinet 10 includes an inner wall 140 provided to define the first cooling space 110 and the second cooling space 120. The inner wall 140 may extend left and right inside the cabinet 10 to allow the first cooling space 110 and the second cooling space 120 to be arranged up and down. Alternatively, the inner wall 140 may extend up and down inside the cabinet 10 to allow the first cooling space 110 and the second cooling space 120 to be arranged left and right. In addition, the inner wall 140 may be formed to be inclined or curved as necessary.

The inner wall 140 may include a second outlet 122 provided to allow air to flow from the second cooling space 120 to the first cooling space 110. The fan 130 configured to discharge the air inside the second cooling space 120 to the first cooling space 110 may be disposed at the second outlet 122 formed on the inner wall 140.

The second inlet 121 may be provided on any side of the cabinet 10. In order to form the wider second inlet 121, the second inlet 121 may be provided on the rear surface of the cabinet 10. The second cooling space 120 may include a plurality of second inlets 121. The heat-generating elements 30 and 40 may be disposed between the second inlet 121 and the second outlet 122.

The fan 130 may be configured to discharge air toward the first outlet 112 of the first cooling space 110. The second outlet 122 formed on the inner wall 140 may be disposed to face the first outlet 112 of the first cooling space 110. The inner wall 140 may be formed in the form of a step descending from the first inlet 111 toward the first outlet 112 of the first cooling space 110, and a second outlet 122 may be formed on a vertical surface of the step.

Although not shown in the drawing, the display apparatus 1 may include a plurality of fans 130. The inner wall 140 may include a plurality of steps, and may include a second outlet 122 on a vertical surface of each step. Each fan 130 may be disposed at each second outlet 122 and configured to discharge air toward the first outlet 112 of the first cooling space 110.

The fan 130 introduces air into the first cooling space 110 at high speed through the second outlet 122. Accordingly, a flow rate of air inside the first cooling space 110 increases, and an internal pressure of the first cooling space decreases. Accordingly, the outside air of the cabinet 10 is introduced through the first inlet 111 of the first cooling space 110.

The fan 130 may include a centrifugal fan configured to discharge air in a circumferential direction by a centrifugal force. The fan 130 may include an axial fan configured to discharge air in an axial direction. Centrifugal fans may be appropriate to be installed in the cabinet 10 that is thin.

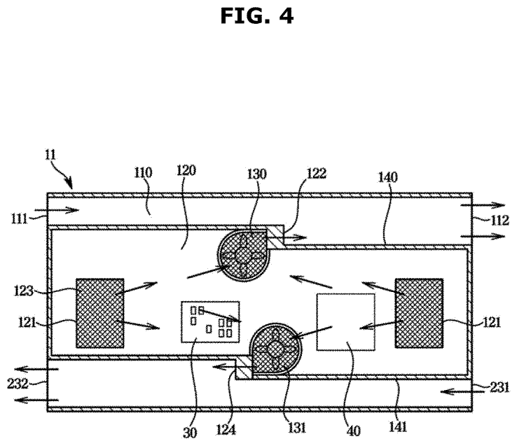

FIG. 4 is a front view of a cabinet of a display apparatus according to another embodiment of the present disclosure.

Referring to FIG. 4, a cabinet 11 may include a third cooling space 230 in addition to the first cooling space 110 and the second cooling space 120. The third cooling space 230 may be configured to be the same as or similar to the first cooling space 110. The third cooling space 230 includes a third inlet 231 provided to allow air outside the cabinet 11 to be introduced, and a third outlet 232 provided to allow air to be discharged to an outside of the cabinet 11.

The first inlet 111 and the first outlet 112 may be disposed to face each other. The first inlet 111 and the first outlet 112 may be provided on sides of the cabinet 11 facing each other. The third inlet 231 and the third outlet 232 may be disposed to face each other. The third inlet 231 and the third outlet 232 may be provided on sides of the cabinet 11 facing each other.

The first cooling space 110 may be disposed on one side of the second cooling space 120, and the third cooling space 230 may be disposed on the opposite side of the second cooling space 120. The cabinet 11 may include a first inner wall 140 provided to define the first cooling space 110 and the second cooling space, and a second inner wall 141 provided to define the second cooling space 120 and the third cooling space 230.

The display apparatus 1 may include a first fan 120 configured to discharge air inside the second cooling space 120 to the first cooling space 110, and a second fan 131 configured to discharge air inside the second cooling space 120 to the third cooling space 230. The first inner wall 140 may include a second outlet 122 provided to allow air to flow from the second cooling space 120 to the first cooling space 110. The second inner wall may include a fourth outlet 124 provided to allow air to flow from the second cooling space 120 to the third cooling space 230. The first fan 130 may be disposed at the second outlet 122 formed in the first inner wall 140. The second fan 131 may be disposed at the fourth outlet 124 formed in the second inner wall 141.

The first fan 130 may be configured to discharge air toward the first outlet 112 of the first cooling space 110. The second fan 131 may be configured to discharge air toward the third outlet 232 of the third cooling space 230. The second outlet 122 formed in the first inner wall 140 may be disposed to face the first outlet 112 of the first cooling space 110. The fourth outlet 124 formed in the second inner wall 141 may be disposed to face the third outlet 232 of the third cooling space 230.

The first inner wall 140 may be formed in the form of a step descending from the first inlet 111 toward the first outlet 112 of the first cooling space 110, and the second outlet 122 may be formed on a vertical surface of the step. The second inner wall 141 may be formed in the form of a step descending from the third inlet 231 toward the third outlet 232 of the third cooling space 230, and the fourth outlet 124 may be formed on a vertical surface of the step.

The third cooling space 230 may be disposed horizontally and vertically symmetrical with the first cooling space 110. The first inlet 111 of the first cooling space 110 and the third inlet 231 of the third cooling space 230 may be provided on sides of the cabinet 11 facing each other. The first outlet 112 of the first cooling space 110 and the third outlet 232 of the third cooling space 230 may be provided on sides of the cabinet 11 facing each other. The first fan 130 and the second fan 131 may be disposed to discharge air in opposite directions to each other.

Although not shown in the drawings, the first cooling space 110 and the third cooling space 230 may be arranged in a vertically symmetrical manner. In this case, the first inlet 111 and the third inlet 231 may be provided on the same side of the cabinet 11, and the first outlet 112 and the third outlet 232 may be provided on the other same side of the cabinet 11. The first fan 130 and the second fan 131 may be disposed to discharge air to the same direction.

Although not shown in the drawing, the display apparatus may include a plurality of fans disposed on the first inner wall 140 and a plurality of fans disposed on the second inner wall 141. The first inner wall 140 may include a plurality of steps, and may include a second outlet 122 on a vertical surface of each step. The second inner wall 141 may include a plurality of steps, and may include a fourth outlet 124 on a vertical surface of each step. Each fan may be arranged on each of the second outlet 122 and the fourth outlet 124, and thus the each fan may be configured discharge air toward the first outlet 112 of the first cooling space 110 and the third outlet 232 of the third cooling space 230.

Although not shown in the drawings, the display apparatus 1 may include a plurality of cooling spaces configured in the same or similar to the first cooling space and the third cooling space 230.

Although not shown in the drawings, the display apparatus 1 may include another cooling space configured in the same or similar to the second cooling space 120. For example, the display apparatus 1 may include a sub-cooling space formed in such a way that the second cooling space 120 shown in FIG. 4 is divided into two. Air inside a first sub cooling space may be discharged to the first cooling space 110 by the first fan 130, and air inside a second sub cooling space may be discharged to the third cooling space 230 by the second fan.

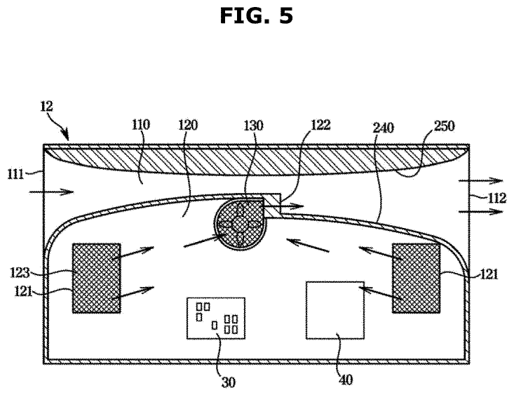

FIG. 5 is a front view of a cabinet of a display apparatus according to still another embodiment of the present disclosure.

Referring to FIG. 5, a cabinet 12 may include a surface 250 formed to be convex toward an inside of the first cooling space 110 to allow an area of a cross section, which is perpendicular to an air flow direction, of the first cooling space 110 to be reduced. Among the surfaces surrounding the first cooling space 110, at least one surface 250 other than the surface, on which the first inlet 111 and the first outlet 112 are provided, may be formed to be convex toward the inside of the first cooling space 110.

The fan 130 may be disposed adjacent to a region having the smallest cross-sectional area of the first cooling space 110. The fan 130 may be disposed on a region having the smallest cross-sectional area of the first cooling space 110 so as to discharge air into the first cooling space 110. A flow rate of air increases in a region where the area of the cross section perpendicular to the air flow direction is reduced. In response to that the fan 130 discharges air into the first cooling space 110 at a high speed in the region where the cross-sectional area of the first cooling space 110 is reduced, an internal pressure of the first cooling space 110 may be more efficiently reduced, and thus the outside air of the cabinet 12 may be more efficiently introduced into the first cooling space 110 through the first inlet 111.

The cabinet 12 includes an inner wall 240 provided to define the first cooling space 110 and the second cooling space 120. The inner wall 240 is also one of the surfaces surrounding the first cooling space 110. The inner wall 240 may be formed to be convex toward an inside of the first cooling space 110 to allow an area of a cross section, which is perpendicular to the air flow direction, of the first cooling space 110 to be reduced.

The inner wall 240 may include a second outlet 122 provided to allow air to flow from the second cooling space 120 to the first cooling space 110. The second outlet 122 may be provided adjacent to a region having the smallest cross-sectional area of the first cooling space 110. The second outlet 122 may be provided at a region where the inner wall 240 protrudes the most toward the inside of the first cooling space 110. The fan 130 configured to discharge the inside air of the second cooling space 120 to the first cooling space 110 may be disposed at the second outlet 122 formed on the inner wall 240.

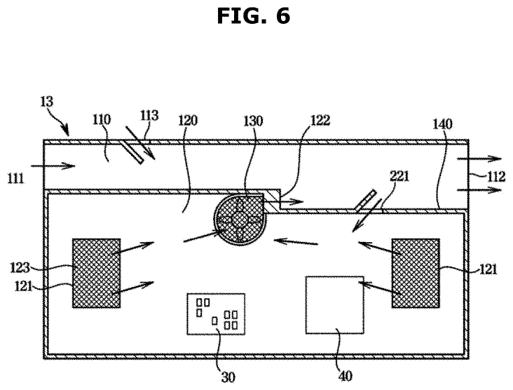

FIG. 6 is a front view of a cabinet of a display apparatus according to still another embodiment of the present disclosure.

Referring to FIG. 6, a cabinet 13 includes a first inlet 111 provided to allow air outside the cabinet 13 to flow into the first cooling space 110 and a second outlet 112 provided to allow air inside the first cooling space 110 to be discharged to an outside of the cabinet 13. The first inlet 111 and the second outlet 122 may be disposed to face each other. The first inlet 111 and the first outlet 112 may be provided on sides of the cabinet 13 facing each other.

The cabinet 13 may further include a first auxiliary inlet 113 provided on a surface, on which the first inlet 111 or the first outlet 112 is not formed, among surfaces surrounding the first cooling space 110. The first auxiliary inlet 113 may be disposed adjacent to the first inlet 111. The cabinet 13 may include a first guide member provided to guide a direction of air flowing into the first cooling space 110 through the first auxiliary inlet 113. The first guide member may be disposed adjacent to the first auxiliary inlet 113. The first guide member may guide air, which is introduced through the first auxiliary inlet 113, toward the first outlet 112 of the first cooling space.

The cabinet 13 includes an inner wall 140 provided to define the first cooling space 110 and the second cooling space 120. The inner wall 140 may include a second outlet 122 provided to allow air to flow from the second cooling space 120 to the first cooling space 110. The inner wall 140 may include a second auxiliary inlet 221 provided to allow air inside the first cooling space 110 to flow into the second cooling space 120. The second auxiliary inlet 221 may be disposed between the second outlet and the first outlet 112 of the first cooling space 110.

The cabinet 13 may include a second guide member disposed adjacent to the second auxiliary inlet 221. The second guide member may guide air, which flows from the second outlet 122, to be discharged to the first outlet 112 without being disturbed by the air flowing into the second auxiliary inlet 221. In addition, the second guide member prevents air, which flows into the second auxiliary inlet 221, from being disturbed by the air flowing from the second outlet 122. A filter provided to filter out dust and moisture may be disposed at the second auxiliary inlet 221.

Although not shown in the drawings, the cabinet 13 may include a plurality of first auxiliary inlets 113 or a plurality of second auxiliary inlets 221.

While the present disclosure has been particularly described with reference to exemplary embodiments, it should be understood by those of skilled in the art that various changes in form and details may be made without departing from the spirit and scope of the present disclosure.

1. A display apparatus comprising:
a display panel;
a cabinet provided to support the display panel and comprising a first cooling space and a second cooling space;
a first inlet provided to allow air outside the cabinet to flow into the first cooling space;
a second inlet provided to allow air outside the cabinet to flow into the second cooling space;
a first fan configured to discharge air inside the second cooling space to the first cooling space; and
a first outlet provided to allow air to flow from the first cooling space to an outside of the cabinet.

2. The display apparatus of claim 1, further comprising:
a heat-generating element disposed in the second cooling space.

3. The display apparatus of claim 1, wherein
the first fan is configured to discharge air toward the first outlet.

4. The display apparatus of claim 1, wherein
the first fan comprises a centrifugal fan.

5. The display apparatus of claim 1, further comprising:
a filter disposed in the second inlet.

6. The display apparatus of claim 1, wherein
the cabinet further comprises a third cooling space, and
the display apparatus further comprises a second fan configured to discharge air to the third cooling space.

7. The display apparatus of claim 6, wherein
the first cooling space is disposed on one side of the second cooling space and the third cooling space is disposed on an opposite side of the second cooling space.

8. The display apparatus of claim 6, wherein
the outlet of the first cooling space and an outlet of the third cooling space are provided on sides of the cabinet facing to each other, and
the first fan and the second fan are disposed to discharge air to opposite directions to each other.

9. The display apparatus of claim 1, wherein
the cabinet comprises an inner wall provided to define the first cooling space and the second cooling space,
wherein the inner wall comprises a second outlet provided to allow air to flow from the second cooling space to the first cooling space, and
the first fan is disposed in the second outlet.

10. The display apparatus of claim 9, wherein
the inner wall is formed to be convex toward an inside of the first cooling space to allow an area of a cross section, which is perpendicular to an air flow direction, of the first cooling space to be reduced, and
the second outlet is disposed adjacent to a region having the smallest cross-sectional area of the first cooling space.

11. The display apparatus of claim 1, wherein
the cabinet comprises a surface formed to be convex toward an inside of the first cooling space to allow an area of a cross section, which is perpendicular to an air flow direction, of the first cooling space to be reduced.

12. The display apparatus of claim 11, wherein
the first fan may be disposed on a region having the smallest cross-sectional area of the first cooling space to allow air to flow into the first cooling space.

13. The display apparatus of claim 1, wherein
the first inlet and the first outlet are provided on sides of the cabinet facing to each other.

14. The display apparatus of claim 13, wherein:
the cabinet further comprises a first auxiliary inlet provided on other side on which the first inlet or the first outlet is not formed.

15. The display apparatus of claim 9, wherein
the inner wall comprises a second auxiliary inlet provided to allow air inside the first cooling space to flow into the second cooling space.
